(19) United States
(12) Patent Application Publication
(10) Pub. No.: US 2017/0330752 A1
(43) Pub. Date: Nov. 16, 2017

(54) METHOD OF MANUFACTURING MEMORY DEVICE

(71) Applicant: SK hynix Inc., Gyeonggi-do (KR)

(72) Inventor: Jin Ha KIM, Gyeonggi-do (KR)

(21) Appl. No.: 15/288,796

(22) Filed: Oct. 7, 2016

(30) Foreign Application Priority Data
May 12, 2016 (KR) 10-2016-0058347

(51) Int. Cl. H01L 21/02; H01L 21/306; H01L 27/11582; H01L 21/324

(52) U.S. Cl. CPC H01L 21/02667; H01L 27/11582; H01L 21/324; H01L 21/02532; H01L 21/02592; H01L 21/30604

(57) ABSTRACT

Provided herein is a method of manufacturing a memory device. The method of manufacturing the memory device includes: forming a compensation layer over the channel layer, wherein an incubation time used for a nucleation of the compensation layer is shorter than an incubation time of the channel layer; and performing a heat treatment process for crystallizing the channel layer.

### CROSS-REFERENCE TO RELATED APPLICATION

The present application claims priority under 35 U.S.C. 119(a) to Korean patent application number 10-2016-0058347 filed on May 12, 2016, which is incorporated herein by reference in its entirety.

### BACKGROUND

### 1. Field

Various embodiments of the present disclosure relate to a method of manufacturing a memory device, and more particularly, to the method of manufacturing a three-dimensional memory device.

### 2. Description of the Related Art

Generally, memory devices may be classified into volatile memory devices and nonvolatile memory devices. A volatile memory device loses data stored therein when a power supply is cut off. On the other hand, a nonvolatile memory device retains data stored therein even if a power supply is cut off. Due to this, the nonvolatile memory device has been widely used as a portable storage device.

A memory device may include a memory cell array for storing data, a peripheral circuit for performing a program operation, a read operation and an erase operation of the memory cell array, and a control logic for controlling the peripheral circuit.

The memory cell array may include a plurality of memory blocks. Recently, because of an increase in the degree of integration, the memory blocks having a three-dimensional structure have been developed. The three-dimensional memory blocks include vertical cell strings, each of which includes a plurality of memory cells stacked in a vertical direction that is perpendicular to a substrate.

The vertical cell strings may be disposed between bit lines and a source line. Each vertical cell string may include a vertical channel layer and a memory layer, and may be coupled with word lines stacked along the memory layer. The memory cells are disposed between the memory layer and the word lines.

### SUMMARY

Various embodiments of the present disclosure are directed to a method of manufacturing a memory device which is capable of improving the charge storage capacity of memory cells of a three-dimensional memory device.

One embodiment of the present disclosure provides method of manufacturing a memory device, comprising: forming a channel layer on a underlying structure; forming a compensation layer over the channel layer, wherein an incubation time used for a nucleation of the compensation layer is shorter than an incubation time of the channel layer; and performing a heat treatment process for crystallizing the channel layer.

Another embodiment of the present disclosure provides a method of manufacturing a memory device, comprising: alternately stacking interlayer insulating layers and sacrificial layers on a underlying structure; forming a vertical hole that vertically passes through the interlayer insulating layers and the sacrificial layers; forming a memory layer along sidewalls of the Interlayer insulating layers and the sacrificial layers that are exposed through a side surface of the vertical hole; forming a channel layer along an inner side surface of the memory layer; forming a compensation layer along an inner side surface of the channel layer, wherein an incubation time used for a nucleation of the compensation layer is shorter than an incubation time of the channel layer; and performing a heat treatment process for crystallizing the channel layer.

Another embodiment of the present disclosure provides a method of manufacturing a memory device, comprising: alternately stacking interlayer insulating layers and sacrificial layers on a underlying structure; forming a vertical hole that passes through the interlayer insulating layers and the sacrificial layers; forming a memory layer along sidewalls of the interlayer insulating layers and the sacrificial layers that are exposed through a side surface of the vertical hole; forming an amorphous silicon layer as a channel layer along an inner side surface of the memory layer; forming a silicon-germanium layer as a compensation layer along an inner side surface of the channel layer; and performing a heat treatment process for crystallizing the channel layer.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory system in accordance with the present disclosure;

FIG. 2 is a detailed diagram of a memory chip shown in FIG. 1;

FIGS. 3 and 4 are perspective views illustrating embodiments of a three-dimensional memory block;

FIGS. 5A and 5B are cross-sectional views illustrating a method of manufacturing a channel layer in accordance with an embodiment of the present disclosure;

FIGS. 6A and 6B are cross-sectional views illustrating a method of manufacturing a channel layer in accordance with an embodiment of the present disclosure;

FIGS. 7A to 7I are cross-sectional views illustrating a method of manufacturing a memory device in accordance with an embodiment of the present disclosure;

FIG. 8 is a diagram illustrating a memory system in accordance with an embodiment of the present disclosure; and

FIG. 9 is a diagram illustrating a computing system in accordance with an embodiment of the present disclosure.

### DETAILED DESCRIPTION

Hereinafter, embodiments will be described in greater detail with reference to the accompanying drawings. Embodiments are described herein with reference to cross-sectional illustrations that are schematic illustrations of embodiments (and intermediate structures). As such, variations from the shapes of the Illustrations as a result, for example, of manufacturing techniques and/or tolerances, are to be expected. Thus, embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements.

Terms such as ‘first’ and ‘second’ may be used to describe various components, but they should not limit the various components. Those terms are only used for the purpose of differentiating a component from other components. For example, a first component may be referred to as a second component, and a second component may be referred to as a first component and so forth without departing from the spirit and scope of the present disclosure. Furthermore, ‘and/or’ may include any one of or a combination of the components mentioned.

Furthermore, a singular form may include a plural from as long as it is not specifically mentioned in a sentence. Furthermore, “Include/comprise” or “Including/comprising” used in the specification represents that one or more components, steps, operations, and elements exist or are added.

Furthermore, unless defined otherwise, all the terms used in this specification including technical and scientific terms have the same meanings as would be generally understood by those skilled in the related art. The terms defined in generally used dictionaries should be construed as having the same meanings as would be construed in the context of the related art, and unless clearly defined otherwise in this specification, should not be construed as having idealistic or overly formal meanings.

It is also noted that in this specification, “connected/coupled” refers to one component not only directly coupling another component but also indirectly coupling another component through an intermediate component. On the other hand, “directly connected/directly coupled” refers to one component directly coupling another component without an intermediate component.

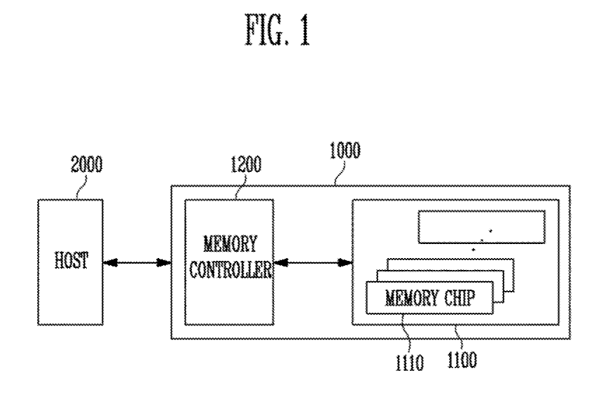

FIG. 1 is a diagram illustrating a memory system in accordance with the present disclosure.

Referring to FIG. 1, the memory system 1000 may include a memory device 1100 configured to store data, and a memory controller 1200 for controlling the memory device 1100.

The memory device 1100 may include a plurality of memory chips 1110. The memory chips 1110 may include a DDR SDRAM (Double Data Rate Synchronous Dynamic Random Access Memory), an LPDDR4 (Low Power Double Data Rate4) SDRAM, a GDDR (Graphics Double Data Rate) SDRAM, an LPDDR (Low Power DDR), a RDRAM (Rambus Dynamic Random Access Memory) or a flash memory. In the following embodiment, the memory chip 1110 including a NAND flash memory will be explained by way of example.

The memory controller 1200 may control the overall operation of the memory device 1100 and may output a command, an address and data for controlling the memory device 1100 to the memory device 1100 in response to a command received from a host 2000 or receives data from the memory device 1100.

The host 2000 may communicate with the memory system 1000 through an interface protocol such as PCI-E (Peripheral Component Interconnect-Express), ATA (Advanced Technology Attachment), SATA (Serial ATA), PATA (Parallel ATA) or SAS (serial attached SCSI).

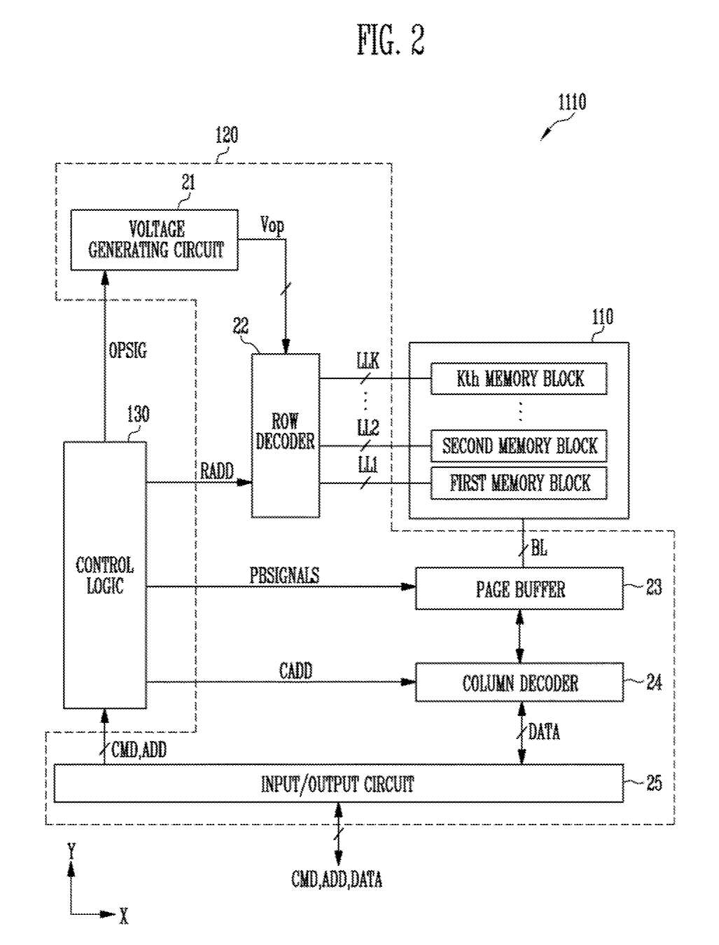

FIG. 2 is a detailed diagram of the memory chip 1110 shown in FIG. 1.

Referring to FIG. 2, the memory chip 1110 may include a memory cell array 110 which stores data, a peripheral circuit 120 that may perform a program operation, a read operation or an erase operation of the memory cell array 110, and a control logic 130 that may control the peripheral circuit 120.

The memory cell array 110 may include first to Kₜₕ memory blocks (K is a positive integer) having substantially the same configuration. The first to Kₜₕ memory blocks may be respectively coupled to first to Kₜₕ local lines LL1 to LLK. Each of the first to Kₜₕ memory blocks may have a three-dimensional structure and have substantially the same configuration.

The peripheral circuit 120 may include a voltage generating circuit 21, a row decoder 22, a page buffer 23, a column decoder 24 and an input/output circuit 25.

The voltage generating circuit 21 may generate operating voltages Vop having various levels in response to an operation signal OPSIG and selectively apply the generated operating voltages Vop to global lines. If the voltage generating circuit 21 receives an operation signal OPSIG corresponding to a program, read or erase operation, the voltage generating circuit 21 may generate operating voltages Vop having various levels needed for the program, read or erase operation.

The row decoder 22 transmits operating voltages Vop to, among the first to Kₜₕ local lines LL1 to LLK, local lines coupled to a selected memory block, in response to a row address RADD. For example, the row decoder 22 is coupled to the voltage generating circuit 21 through global lines, and transmits operating voltages Vop received through the global lines, to local lines coupled to the selected memory block.

The page buffer 23 is coupled to the memory cell array 110 through bit lines. In response to page buffer control signals PBSIGNALS, the page buffer 23 precharges the bit lines to a positive voltage, exchanges data with the selected memory block during a program or read operation, or temporarily stores received data.

The column decoder 24 exchanges data DATA between the page buffer 23 and the input/output circuit 25 in response to a column address CADD.

The input/output circuit 25 may transmit a command CMD and an address ADD received from the memory controller 1200 to the control logic 120, transmit data received from an external device to the column decoder 24, or output data received from the column decoder 24 to the external device.

The control logic 130 controls the peripheral circuit 120 in response to the command CMD and the address ADD. For example, the control logic 130 may output an operation signal OPSIG, a row address RADD, a page buffer control signal PBSIGNALS and a column address CADD for controlling the peripheral circuit 120, in response to the command CMD and the address ADD.

The above-described first to Kₜₕ memory blocks each having a three-dimensional structure have substantially the same configuration. Therefore, any one of the first to Kₜₕ memory blocks will be explained by way of example.

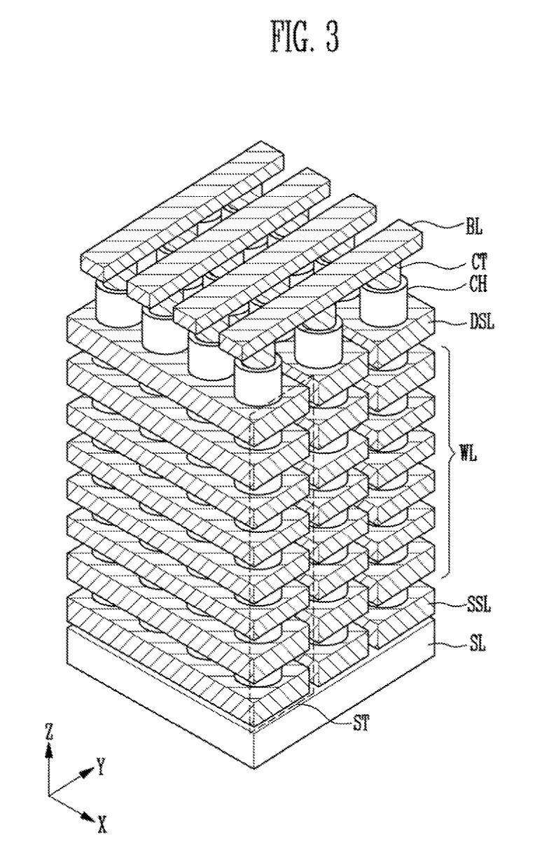

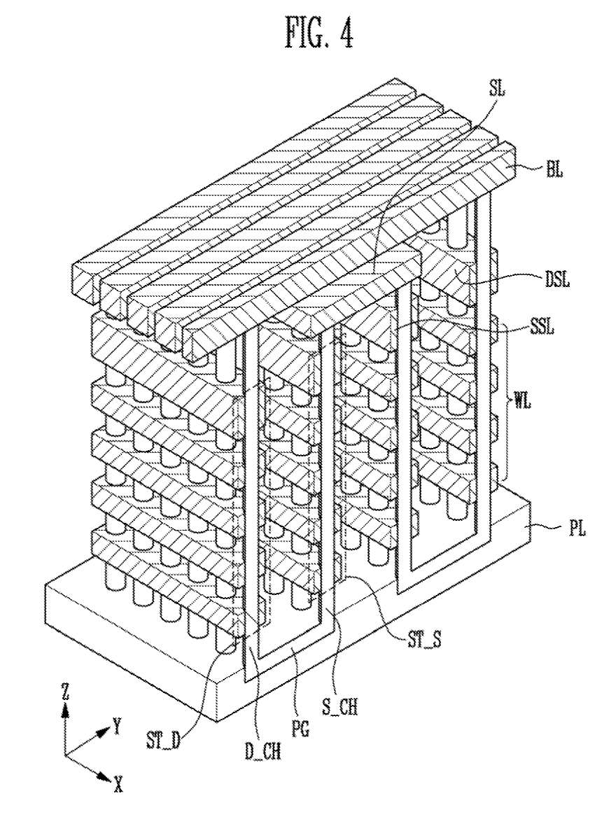

FIGS. 3 and 4 are perspective views illustrating embodiments of the three-dimensional memory block.

Referring to FIG. 3, the memory block having a three-dimensional structure may include strings ST that are arranged in a vertical direction (Z-direction) on a substrate and are embodied in an I shape. The strings ST may be disposed between bit lines BL and a source line SL. The foregoing structure may refer to a BiCS (Bit Cost Scalable) structure. For example, when the source line SL is horizontally formed over the substrate, the strings ST having the BiCS structure may be formed in the vertical direction over the source line SL. In more detail, the strings ST may include source select lines SSL, word lines WL and drain select lines DSL which are arranged in a first direction (i.e., Y-direction) and stacked to be spaced apart from each other. The numbers of source select lines SSL, word lines WL and drain select lines DSL are not limited to those shown in FIG. 3 and may be changed depending on memory devices. The strings ST may include vertical channel layers CH which vertically pass through the source select lines SSL, the word lines WL and the drain select lines, and bit lines BL which come into contact with upper ends of the vertical channel layers CH protruding upward from the drain select lines and are arranged in a second direction (i.e., X-direction) perpendicular to the first direction (i.e., Y-direction). Memory cells may be formed between the word lines WL and the vertical channel layers CH. Contact plugs CT may be further formed between the bit lines BL and the vertical channel layers CH. Among memory cells coupled to different strings ST, a group of memory cells coupled to the same word line may refer to a page.

Referring to FIG. 4, a memory block embodied in a three dimensional structure may include strings ST_S and ST_D which are arranged in a vertical direction (i.e., Z-direction) on a substrate and embodied in a U shape. The strings ST_S and ST_D may include source strings ST_S coupled to the source line SL and drain strings ST_D coupled to the bit lines BL. The source strings ST_S and the drain strings ST_D may be coupled each other through a pipe channel P_CH and formed in a U shape. The pipe channel P_CH may be formed in a pipe line PL. In detail, the source strings ST_S are vertically disposed between source lines SL and the pipe line PL. The drain strings ST_D are vertically disposed between the bit lines BL and the pipe line PL. The forgoing structure may refer to a P-BiCS (Pipe-shaped Bit Cost Scalable) structure.

In more detail, the drain strings ST_D may include word lines WL and drain select lines DSL which are arranged in the first direction (i.e., Y-direction) and stacked to be spaced apart from each other, and drain vertical-channel layers D_CH which vertically pass through the word lines WL and the drain select lines DSL. The source strings ST_S may include word lines WL and source select lines SSL which are arranged in the first direction (I.e., Y-direction) and stacked to be spaced apart each other, and source vertical-channel layers S_CH which vertically pass through the word lines WL and the source select lines SSL. The drain vertical-channel layers D_CH and the source vertical-channel layers S_CH may be coupled each other by the pipe channel layers P_CH in the pipe line PL. The bit lines BL may come into contact with upper ends of the drain vertical-channel layers D_CH that protrude upward from the drain select lines DSL and are arranged in the second direction (i.e., X-direction) perpendicular to the first direction (i.e., Y-direction). Memory cells may be formed between the word lines WL and the vertical channel layers S-CH or D_CH.

Each of the channel layers CH, D_CH, S_CH and P_CH described with reference to FIGS. 3 and 4 may be formed of a poly-silicon layer. The currents of strings may be changed depending on resistance of the channel layers CH, D_CH, S_CH and P_CH, and particularly depending on grain sizes of the channel layers CH, D_CH, S_CH and P_CH. For example, the more the grain sizes of the channel layers CH, D_CH, S_CH and P_CH increase, the lower the resistance of the channel layers CH, D_CH, S_CH and P_CH is. Due to this, during the operation of the memory device, current flowing through the memory cells may increase. In an embodiment of the present disclosure, a manufacturing method capable of increasing the grain sizes of the channel layers is proposed as follows.

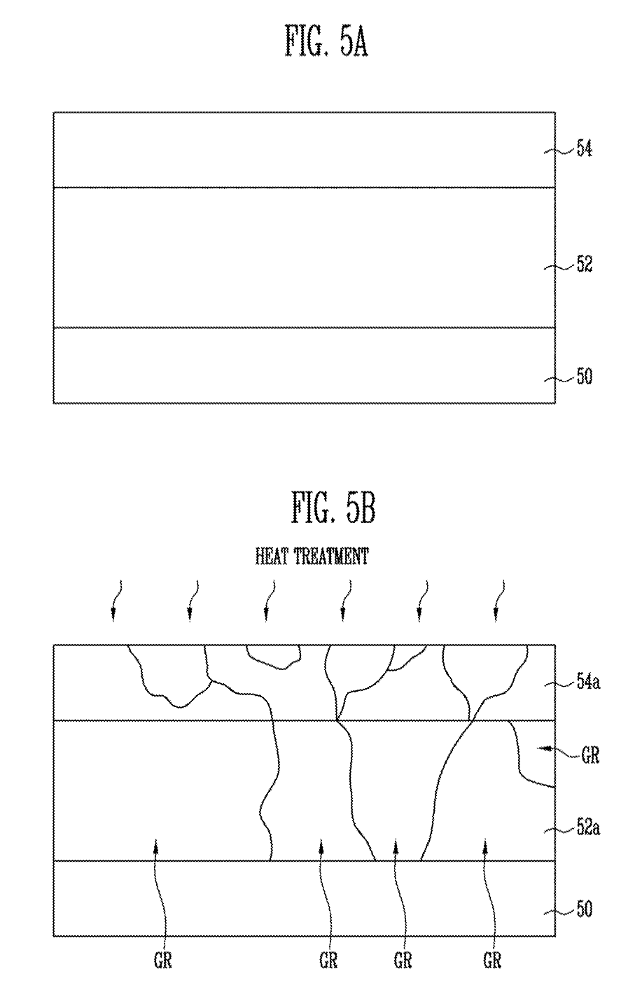

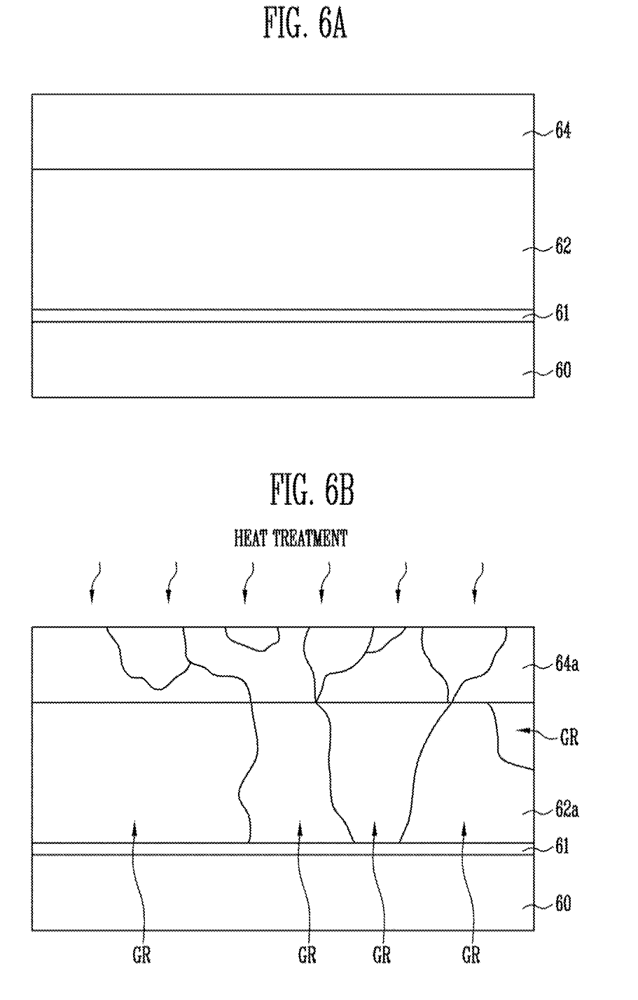

FIGS. 5A and 5B are cross-sectional views illustrating a method of manufacturing a channel layer in accordance with an embodiment of the present disclosure.

Referring to FIG. 5A, a channel layer 52 is formed on an underlying structure 50. The underlying structure 50 may be formed of a semiconductor substrate, a memory layer, a conductive layer or an insulating layer. The channel layer 52 may be formed of an amorphous silicon layer. The channel layer 52 may be formed at a temperature at which a silicon layer is not crystallized. For example, the channel layer 52 may be formed under temperatures ranging from 500° C. to 600° C.

Subsequently, a compensation lay 54 is formed on the channel layer 52. The compensation layer 54 may be used to increase the grain size of the channel layer 52. An incubation time used for a nucleation of the compensation layer 54 is shorter than that of the channel layer 52. For example, the compensation layer 54 may be formed of a silicon-germanium layer. The more the concentration of germanium in the silicon-germanium increases, the more the grain size of the channel layer 52 may increase during a following crystallization process. However, as the grain size of the channel layer 52 increases, morphology characteristics of the channel layer 52 may deteriorate. Given this, the concentration of germanium in the silicon-germanium layer may be controlled. For example, the concentration of germanium may have a range from 20% to 80%.

Referring to FIG. 5B, the crystallization process for crystallizing the channel layer 52 is performed after the compensation layer 54 has been formed on the channel layer 52. The crystallization process may be embodied by a heat treatment process. The grain size of the channel layer 52 may vary depending on the temperature and time of the heat treatment process. Therefore, the temperature and time of the heat treatment process are appropriately adjusted to increase the grain size of the channel layer 52. For example, during a heat treatment process, the temperature may have a range from 350° C. to 650° C., and the time may have a range from two hours to four hours. Also, the heat treatment process may be performed under an atmosphere of nitrogen (N₂).

If the heat treatment process is performed under the above-mentioned conditions, the compensation layer 54 is crystallized more rapidly than the channel layer 52 and is changed to a crystallized compensation layer 54a. When the compensation layer 54 is changed to the crystallized compensation layer 54a, the crystallized compensation layer 54a may be formed by the growth of grains on a surface of the compensation layer 54. When grains grow on the surface of the compensation layer 54, the channel layer 52 may be changed to the crystallized channel layer 52a by epitaxy growth.

If the crystallization process is performed under the above-described conditions, the size of grains GR of the crystallized channel layer 52a may be formed to be large.

FIGS. 6A and 6B are cross-sectional views illustrating a method of manufacturing channel layer in accordance with another embodiment of the present disclosure.

Referring to FIG. 6A, a seed layer 61 and a channel layer 62 are formed on an underlying structure 60. The underlying structure 60 may be formed of a semiconductor substrate, a memory layer, a conductive layer or an Insulating layer. The seed layer 61 may promote the growth of the channel layer 62, and may be formed on a surface of the underlying structure 60 before the channel layer 62 is formed. The seed layer 61 may be formed of the same material as that of the channel layer 62. The seed layer 61 may be formed under various temperatures and, for example, formed in temperatures ranging from 350° C. to 400° C. The channel layer 62 may be formed of an amorphous silicon layer. The channel layer 62 may be formed in various temperatures and, for example, formed under temperatures ranging from 500° C. to 600° C.

Thereafter, a compensation layer 64 is formed on the channel layer 62. The compensation layer 64 may be used to increase the grain size of the channel layer 62. An incubation time used for a nucleation of the compensation layer 64 is shorter than that of the channel layer 62. For example, the compensation layer 64 may be formed of a silicon-germanium layer. The concentration of germanium in the silicon-germanium layer may have a range from 20% to 80%. The more the concentration of germanium increases, the more the grain size of the channel layer 62 increases during a following crystallization process. However, as the concentration of germanium increases, the morphology characteristics of the channel layer 62 may deteriorate. Given this, the temperature and time of the following crystallization process is controlled.

Referring to FIG. 6B, the crystallization process for crystallizing the channel layer 62 is performed after the compensation layer 64 has been formed on the channel layer 62. The crystallization process may be performed in the same manner as that of the crystallization process described with reference to FIG. 5B; therefore, detailed explanation thereof will be omitted. The size of grains GR of the crystallized channel layer 62a may be formed to be large by the crystallization process described with reference to FIG. 5B.

The crystallization process described with reference to FIGS. 5A, 5B, 6A and 6B may be applied to a method of manufacturing a two-dimensional memory device or a three-dimensional memory device.

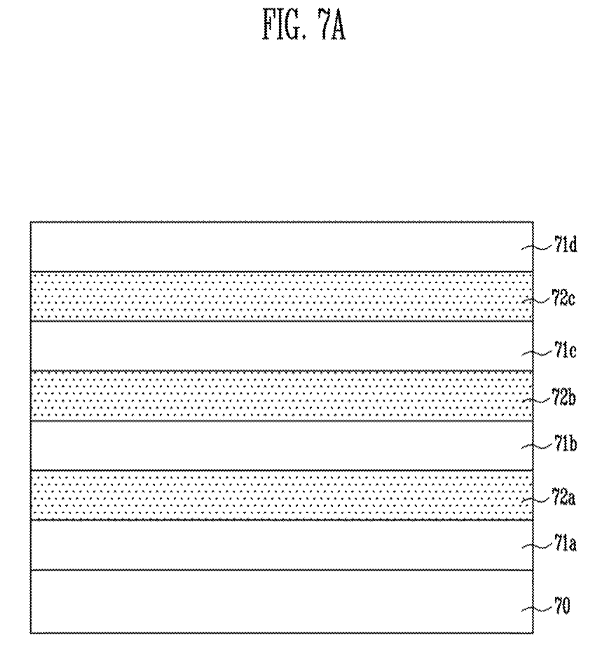

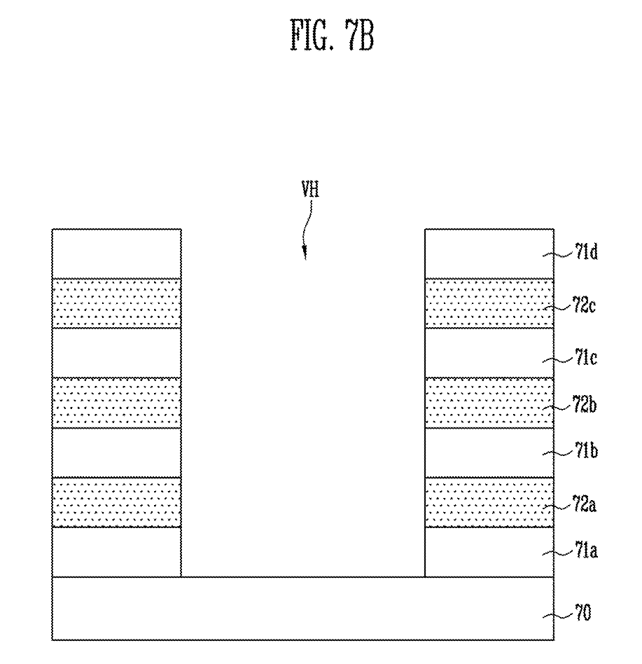

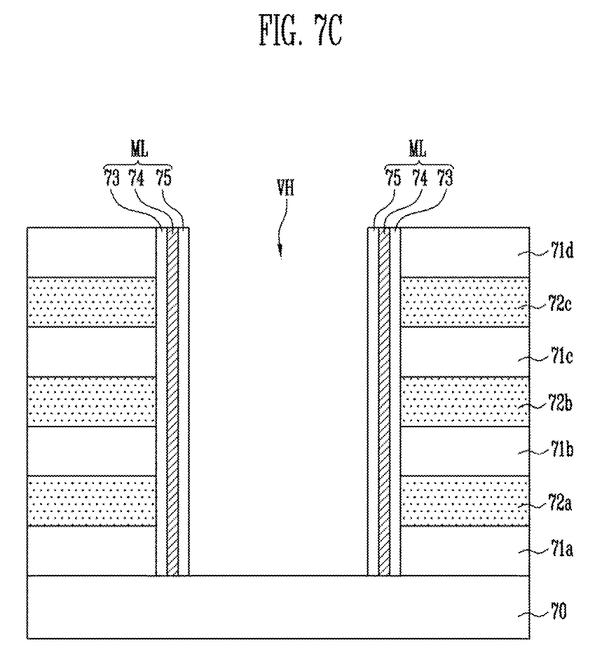

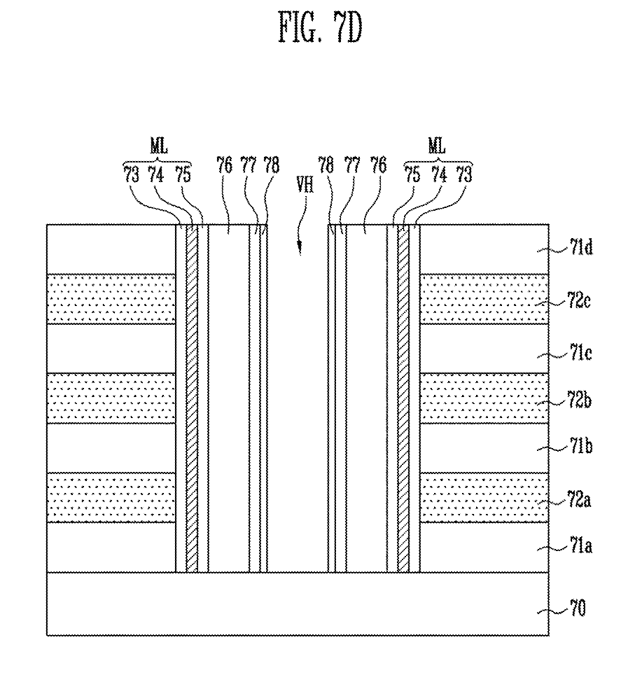

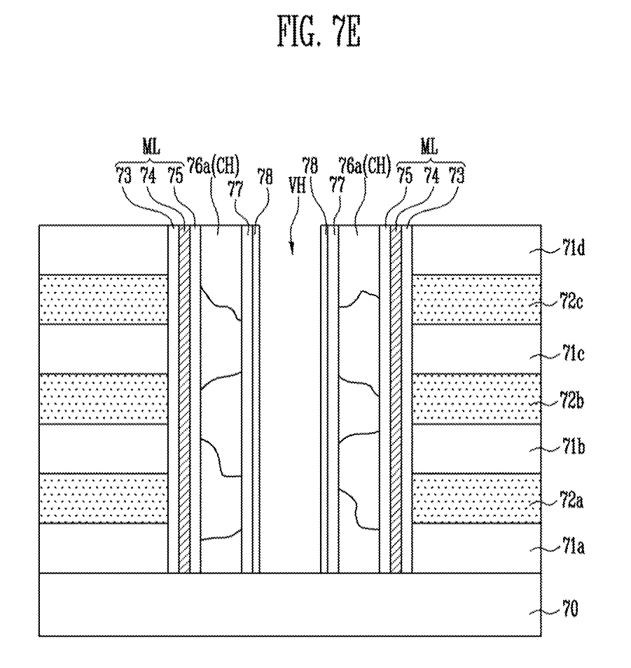

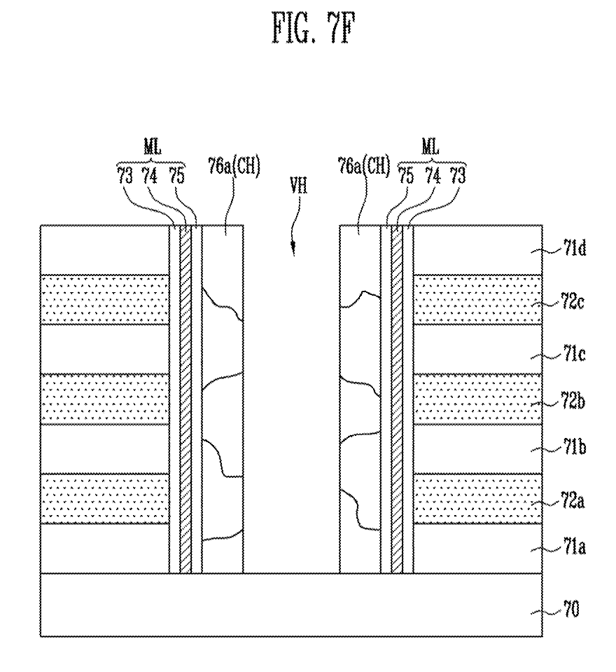

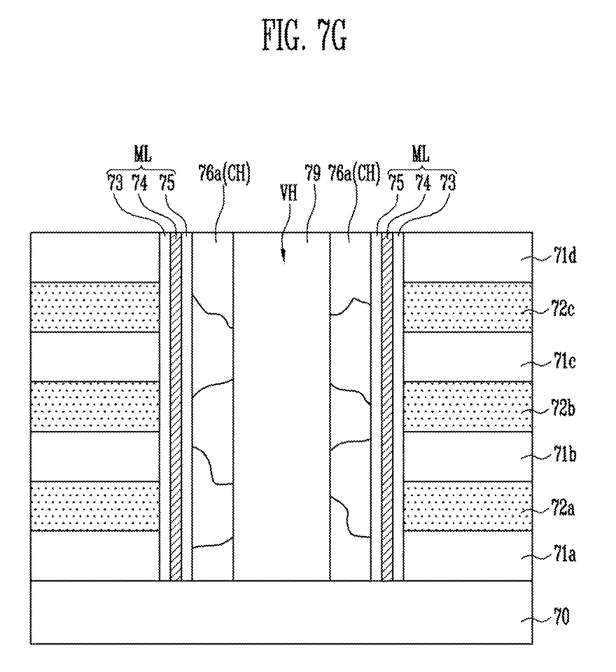

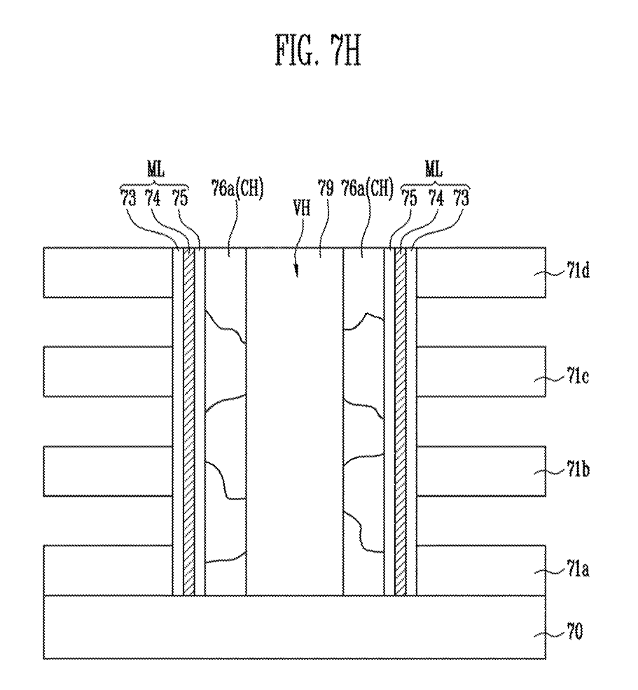

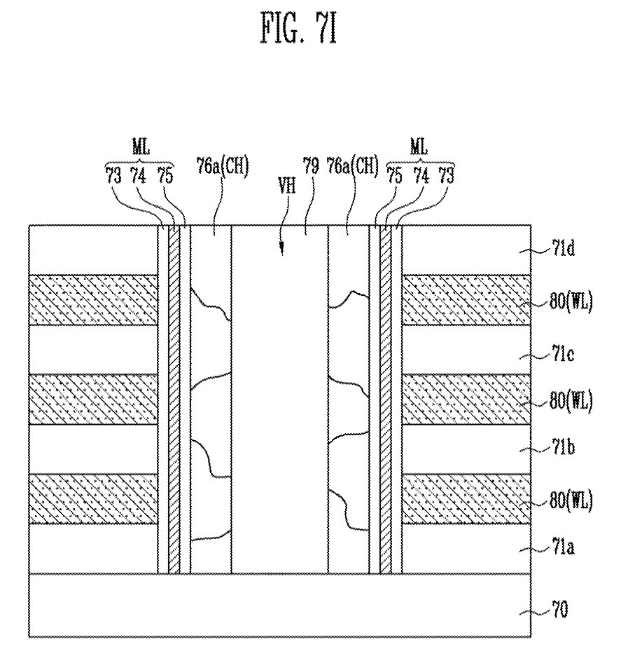

FIGS. 7A to 7I are cross-sectional views illustrating a method of manufacturing a three-dimensional memory device in accordance with an embodiment of the present disclosure.

Referring to FIG. 7A, interlayer insulating layers 71a to 71d and sacrificial layers 72a to 72c are alternately stacked on an underlying structure 70. The underlying structure 70 may include a semiconductor substrate, an insulating layer or a pipe gate. Each of the interlayer insulating layers 71a to 71d may be formed of an oxide layer. Each of the sacrificial layers 72a to 72c may be formed of a nitride layer. The numbers of stacked interlayer insulating layers 71a to 71d and sacrificial layers 72a to 72c may be changed depending on memory devices.

Referring to FIG. 78, a vertical hole VH is formed to vertically pass through the interlayer insulating layers 71a to 71d and the sacrificial layers 72a to 72c. For example, the vertical hole VH may be formed in such a way that a mask pattern having an opening in a region thereof corresponding to a position of the vertical hole VH to be formed is formed on the top of the interlayer insulating layers 71a to 71d and sacrificial layers 72a to 72c, and then an etching process is performed.

Referring to FIG. 7C, a memory layer ML is formed along sidewalls of the interlayer insulating layers 71a to 71d and sacrificial layers 72a to 72c that are exposed on a side surface of the vertical hole VH. The memory layer ML may be formed in a cylindrical shape in the vertical hole VH. The memory layer ML may include a blocking layer 73, a charge trapping layer 74, and a tunnel insulating layer 75. The blocking layer 73 may be formed of an oxide layer. The charge trapping layer 74 may be formed of a nitride layer, and the tunnel insulating layer 75 may be formed of an oxide layer. An etching process may be performed to expose the underlying structure 70 at a bottom of the vertical hole VH.

Referring to FIG. 7D, a channel layer 76 and a compensation layer 77 are successively formed along an inner side surface of the memory layer ML. Each of the channel layer 76 and the compensation layer 77 may be formed in a cylindrical shape along the inner side surface of the memory layer ML in the vertical hole VH. The channel layer 76 may be formed of an amorphous silicon layer. For example, the channel layer 76 may be formed at a temperature at which a silicon layer is not crystallized. In an embodiment, the channel layer 76 may be formed under temperatures ranging from 500° C. to 600° C. A seed layer (not shown) for promoting the growth of the channel layer 76 may be further formed along the inner side surface of the memory layer ML before the channel layer 76 is formed. A method of forming the seed layer (not shown) may be performed in the same manner as the method described with reference to FIG. 6A, and thus detailed explanation thereof will be omitted. The compensation layer 77 may be used to increase the grain size of the channel layer 76 and formed of material having an incubation time shorter than that of the channel layer 76. For example, the compensation 77 may be formed of a silicon-germanium layer. The more the concentration of germanium in the silicon-germanium layer increases, the more the grain size of the channel layer 76 may increase during a following crystallization process. However, as the grain size of the channel layer 76 increases, the morphology characteristics of the channel layer 76 may deteriorate. Given this, the concentration of germanium in the silicon-germanium layer may be controlled and, for example, the concentration of germanium may have a range from 20% to 80%. Also, after the compensation layer 77 has been formed, a liner layer 78 may be further formed along an inner side surface of the compensation layer 77. The liner layer 78 may be formed of an oxide layer. An etching process may be performed to expose the underlying structure 70 at a bottom of the vertical hole VH.

Referring to FIG. 7E, a crystallization process for crystallizing the channel layer 76 is performed. The crystallization process may be embodied by a heat treatment process. During the heat treatment process, the temperature and time may be adjusted in consideration of the grain size and morphology characteristics of the channel layer 76. For example, the heat treatment process may be performed at a temperature ranging from 350° C. to 650° C. under the atmosphere of nitrogen (N₂) for two hours to four hours. If the heat treatment process is performed under the above-described conditions, the channel layer 76 is crystallized and is changed to a crystallized channel layer 76a. The crystallized channel layer 76a may be used as a channel CH of a string. In particular, if the heat treatment process is performed under the above-described conditions, the size of grains forming the crystallized channel layer 76a is increased, so that the resistance of channel CH may be reduced. When the liner layer 78 is formed on the side surface of the compensation layer 77, the liner layer 78 may prevent germanium included in the compensation layer 77 from being removed out of the compensation layer 77 during the heat treatment process.

Referring to FIG. 7F, after the crystallized channel layer 76a has been formed, the compensation layer (77 of FIG. 7E) may be unnecessary. Therefore, an etching process may be performed to remove the compensation layer 77. If the liner layer 78 has been formed, the liner layer 78 and the compensation layer 77 may be removed together during the etching process. The etching process may be embodied by a wet etching process. The wet etching process may be performed using an etchant having an etch selectivity at which an etching rate of silicon-germanium (SiGe) is higher than that of silicon (Si). For example, an etchant of which an etch selectivity of silicon to silicon-germanium is approximately 1:50 may be used.

Referring to FIG. 7G, a vertical insulating layer 79 is formed such that an inner space of the crystallized channel layer 76a formed in a cylindrical shape, in other words, the other region of the vertical hole VH, is filled with the vertical insulating layer 79. The vertical insulating layer 79 may be formed of an oxide layer.

Referring to FIG. 7H, the sacrificial layers (72a to 72c of FIG. 7G) are removed so that recesses are formed between the interlayer insulating layers 71a to 71d.

Referring to FIG. 7I, each of the recesses formed between the interlayer insulating layers 71a to 71d is filled with a conductive layer 80. The conductive layer 80 may be formed of tungsten in order to be used as word lines WL.

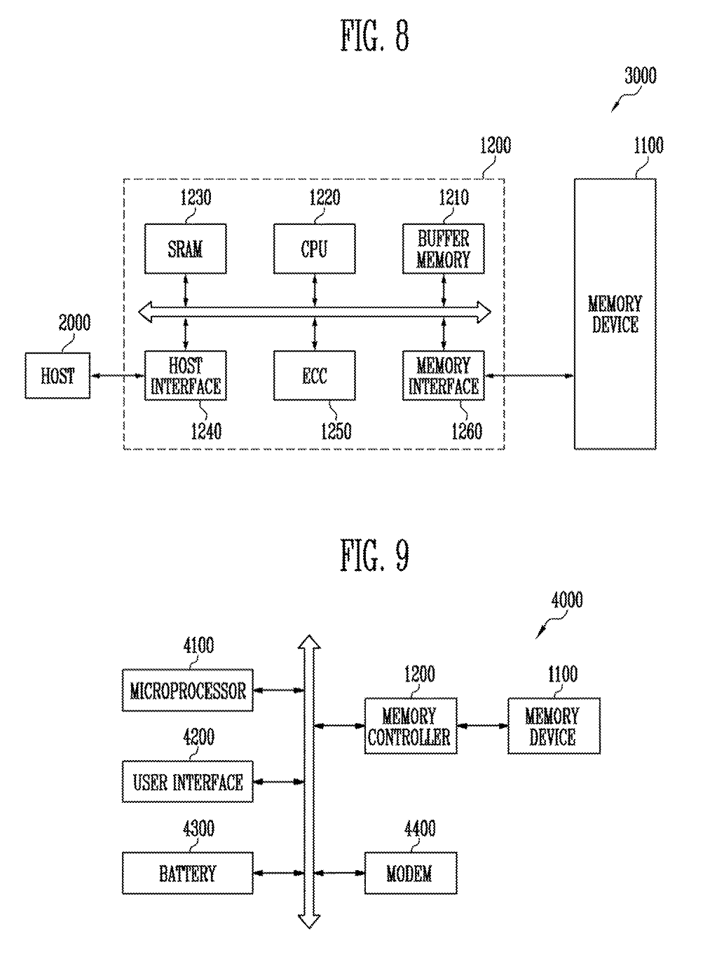

FIG. 8 is a diagram illustrating a memory system 3000 in accordance with an embodiment of the present disclosure.

Referring to FIG. 8, the memory system 3000 may include a memory device 1100 which stores data, and a memory controller 1200 which controls the memory device 1100. The memory controller 1200 controls communication between a host 2000 and the memory device 1100. The memory controller 1200 may include a buffer memory 1210, a CPU 1220, an SRAM 1230, a host interface 1240, an ECC (Error Correction Circuit) 1250 and a memory interface 1260.

The buffer memory 1210 temporarily stores data while the memory controller 1200 controls the memory device 1100. The CPU 1220 may perform control operations for data exchange of the memory controller 1200. The SRAM 1230 may be used as working memory for the CPU 1220. The host interface 1240 may include a data exchange protocol of the host 2000 coupled to the memory system 3000. The ECC 1250, which is an error correction unit, may detect and correct an error included in data read from the memory device 1100. The memory interface 1260 may interface with the memory device 1100. Although not illustrated in FIG. 8, the memory system 3000 may further include a ROM (not shown) for storing code data to interface with the host 2000.

The host 2000 for which the memory system 3000 in accordance with the present disclosure may be used may include a computer, a UMPC (Ultra Mobile PC), workstation, net-book, a PDA (Personal Digital Assistant), a portable computer, a web tablet, a wireless phone, a mobile phone, a smart phone, a digital camera, a digital audio recorder, a digital audio player, a digital picture recorder, a digital picture player, a digital video recorder, a digital video player, a device capable of transmitting/receiving information in a wireless environment, or various devices for forming a home network.

FIG. 9 is a diagram illustrating a computing system 4000 in accordance with an embodiment of the present disclosure.

Referring to FIG. 9, the memory system 4000 may include a memory device 1100, a memory controller 1200, a microprocessor 4100, a user interface 4200 and a modem 4400 which are electrically coupled to a bus. When the memory system 4000 is a mobile device, a battery 4300 may be additionally included to supply an operating voltage of the memory system 4000. Although not shown in the drawings, the memory system 4000 may further include an application chip set, a camera image processor (CIS), a mobile DRAM, or the like. The memory controller 1200 and the memory device 1100 may form an SSD (Solid State Drive/Disk).

The memory system 4000 in accordance of the present disclosure may be mounted using packages of various forms. For example, the memory system 4000 may be mounted using packages such as PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP) and Wafer-Level Processed Stack Package (WSP)

As described above, in a three-dimensional memory device in accordance with the present disclosure, the grain size of a channel layer is increased, whereby current flowing through a channel may be increased. Therefore, electrical characteristics of the memory device may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a memory device, comprising:
forming a channel layer on a underlying structure;
forming a compensation layer over the channel layer, wherein an incubation time used for a nucleation of the compensation layer is shorter than an incubation time of the channel layer; and
performing a heat treatment process for crystallizing the channel layer.

2. The method according to claim 1, wherein the channel layer is formed of an amorphous silicon layer.

3. The method according to claim 1, wherein the compensation layer is formed of a silicon-germanium layer.

4. The method according to claim 3, wherein a concentration of germanium contained in the silicon-germanium layer has a range from approximately 20% to 80%.

5. The method according to claim 1, wherein the heat treatment process is performed at a temperature ranging from approximately 350° C. to 650° C.

6. The method according to claim 1, wherein the heat treatment process is performed under an atmosphere of nitrogen.

7. The method according to claim 1, further comprising, before the forming of the channel layer,
forming a seed layer on the underlying structure.

8. The method according to claim 7, wherein the seed layer is formed of the same material as a material of the channel layer.

9. A method of manufacturing a memory device, comprising:
alternately stacking interlayer insulating layers and sacrificial layers on a underlying structure;
forming a vertical hole that vertically passes through the Interlayer insulating layers and the sacrificial layers;
forming a memory layer along sidewalls of the Interlayer insulating layers and the sacrificial layers that are exposed through a side surface of the vertical hole;
forming a channel layer along an inner side surface of the memory layer;
forming a compensation layer along an inner side surface of the channel layer, wherein an incubation time used for a nucleation of the compensation layer is shorter than an incubation time of the channel layer; and
performing a heat treatment process for crystallizing the channel layer.

10. The method according to claim 9, wherein the channel layer is formed of an amorphous silicon layer.

11. The method according to claim 9, wherein the compensation layer is formed of a silicon-germanium layer.

12. The method according to claim 11, wherein a concentration of the germanium contained in the silicon-germanium layer has a range from approximately 20% to 80%.

13. The method according to claim 9, wherein the heat treatment process is performed at a temperature ranging from approximately 350° C. 15 to 650° C. for two hours to four hours.

14. The method according to claim 9, wherein the heat treatment process is performed under an atmosphere of nitrogen.

15. The method according to claim 9, further comprising, after the performing of the heat treatment process,
performing an etching process for removing the compensation layer.

16. The method according to claim 15, wherein the etching process comprises a wet etching process performed using an etchant having an etch selectivity at which an etching rate of the compensation layer is higher than an etching rate of the channel layer.

17. The method according to claim 9, further comprising, before the forming of the channel layer,
forming a seed layer along the inner side surface of the memory layer.

18. The method according to claim 17, wherein the seed layer is formed of the same material as a material of the cannel layer.

19. A method of manufacturing a memory device, comprising:
alternately stacking interlayer insulating layers and sacrificial layers on a underlying structure;
forming a vertical hole that passes through the interlayer insulating layers and the sacrificial layers;
forming a memory layer along sidewalls of the interlayer insulating layers and the sacrificial layers that are exposed through a side surface of the vertical hole;
forming an amorphous silicon layer as a channel layer along an inner side surface of the memory layer;
forming a silicon-germanium layer as a compensation layer along an inner side surface of the channel layer; and
performing a heat treatment process for crystallizing the channel layer.

20. The method according to claim 19, further comprising, after the performing of the heat treatment process,
performing an etching process for removing the compensation layer.
